(19) United States
(12) Patent Application Publication
(10) Pub. No.: US 2016/0322473 A1
(43) Pub. Date: Nov. 3, 2016

(54) Buffer Layer on Gate and Methods of Forming the Same

(71) Applicant: Taiwan Semiconductor Manufacturing Company, Ltd., Hsin-Chu (TW)

(72) Inventors: Shiu-Ko JangJian, Tainan City (TW); Chi-Wen Liu, Hsin-Chu (TW); Chih-Nan Wu, Tainan City (TW); Chun Che Lin, Tainan City (TW)

(21) Appl. No.: 14/718,245

(22) Filed: May 21, 2015

Related U.S. Application Data
(60) Provisional application No. 62/155,263, filed on Apr. 30, 2015.

(51) Int. Cl. H01L 29/66; H01L 29/78; H01L 29/49

(52) U.S. Cl. CPC H01L 29/66545; H01L 29/49; H01L 29/785; H01L 29/66795

(57) ABSTRACT

Buffer layers on gates and methods of forming such are described. According to a method embodiment, a gate structure is formed. The gate structure includes a gate dielectric over a substrate, a work function tuning layer over the gate dielectric, and a metal-containing material over the work function tuning layer. A buffer layer is formed on the metal-containing material. A dielectric material is formed on the buffer layer. According to a structure embodiment, a gate structure includes a high-k gate dielectric and a metal gate electrode. A buffer layer is on the metal gate electrode. A dielectric cap is on the buffer layer. An inter-layer dielectric is over the substrate and around the gate structure. A top surface of the inter-layer dielectric is co-planar with a top surface of the dielectric cap.

This application claims priority to and the benefit of U.S. Provisional Application No. 62/155,263, filed on Apr. 30, 2015, entitled “Buffer Layer on Gate and Methods of Forming the Same,” which application is hereby incorporated herein by reference in its entirety.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon.

A transistor is an element that is used often in semiconductor devices. There may be a large number of transistors (e.g. hundreds of, thousands of, or millions of transistors) on a single integrated circuit (IC), for example. A common type of transistor used in semiconductor device fabrication is a metal oxide semiconductor field effect transistor (MOSFET), as an example. A planar transistor (e.g. planar MOSFET) typically includes a gate dielectric disposed over a channel region in a substrate, and a gate electrode formed over the gate dielectric. A source region and a drain region of the transistor are formed on either side of the channel region.

Multiple gate field-effect transistors (MuGFETs) are a recent development in semiconductor technology. One type of MuGFET is referred to as a FinFET, which is a transistor structure that includes a fin-shaped semiconductor material that is raised vertically out of the semiconductor surface of an integrated circuit.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an example of a generic fin Field-Effect Transistor (finFET) in a three-dimensional view in accordance with some embodiments.

FIGS. 2, 3, 4A, 4B, 5 through 14, 15A, and 15B are cross-sectional views of intermediate stages in the manufacturing of finFETs in accordance with some embodiments.

FIG. 16 is an enlarged view of a gate structure formed in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Fin Field-Effect Transistors (finFETs) and methods of forming the same are provided in accordance with various embodiments. Intermediate stages of forming finFETs are illustrated. Some embodiments discussed herein are discussed in the context of finFETs formed using a gate-last process. Some embodiments contemplate aspects used in planar devices, such as planar FETs. Some variations of the embodiments are discussed. One of ordinary skill in the art will readily understand other modifications that may be made that are contemplated within the scope of other embodiments. Although method embodiments are discussed in a particular order, various other method embodiments may be performed in any logical order and may include fewer or more steps described herein.

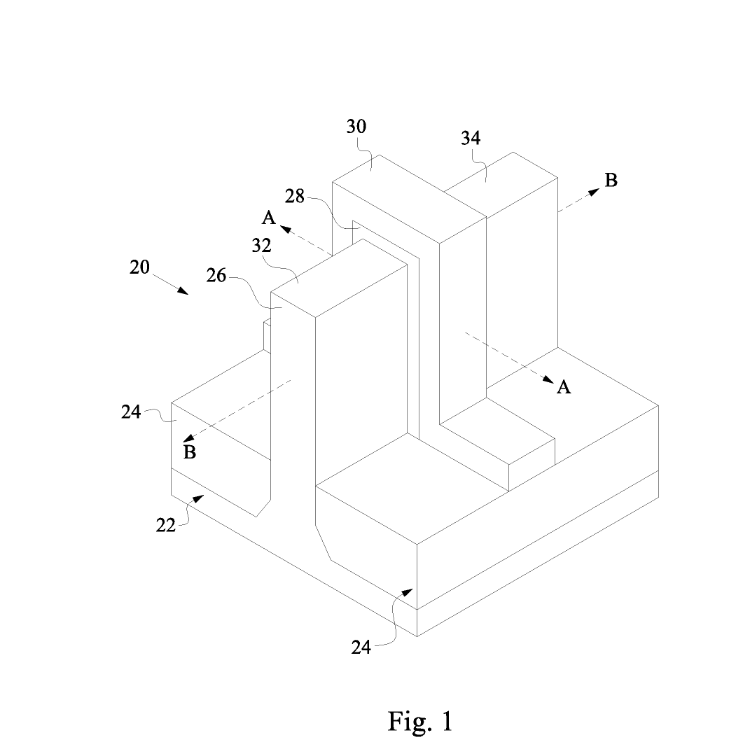

FIG. 1 illustrates an example of a generic finFET 20 in a three-dimensional view. The finFET 20 comprises a fin 26 on a substrate 22. The substrate 22 includes isolation regions 24, and the fin 26 protrudes above and from between neighboring isolation regions 24. A gate dielectric 28 is along sidewalls and over a top surface of the fin 26, and a gate electrode 30 is over the gate dielectric 28. Source/drain regions 32 and 34 are disposed in opposite sides of the fin 26 with respect to the gate dielectric 28 and gate electrode 30. FIG. 1 further illustrates reference cross-sections that are used in later figures. Cross-section A-A is across a channel, gate dielectric 28, and gate electrode 30 of the finFET 20. Cross-section B-B is perpendicular to cross-section A-A and is along a longitudinal axis of the fin 26 and in a direction of, for example, a current flow between the source/drain regions 32 and 34. Subsequent figures refer to these reference cross-sections for clarity.

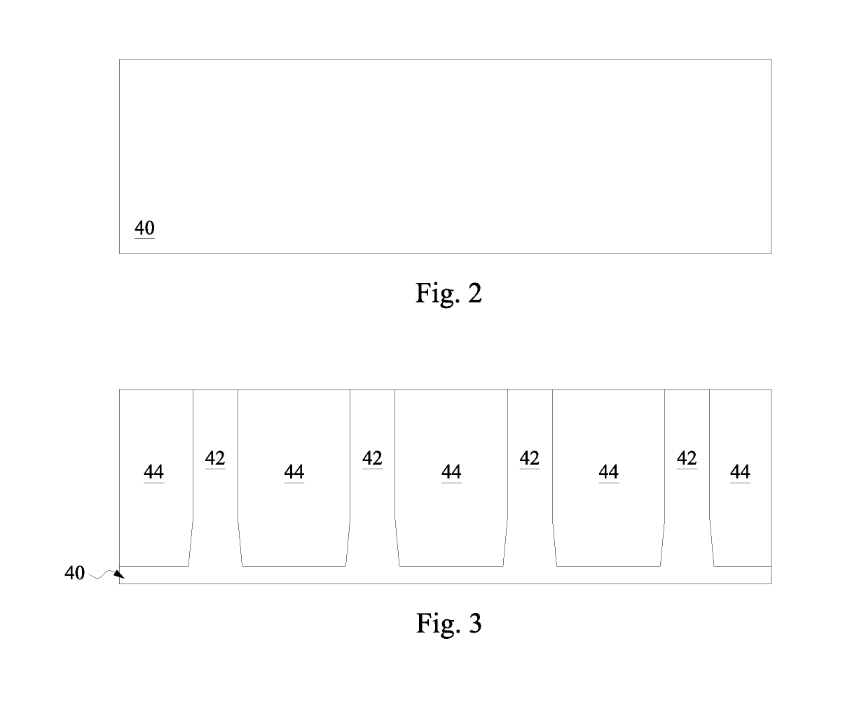

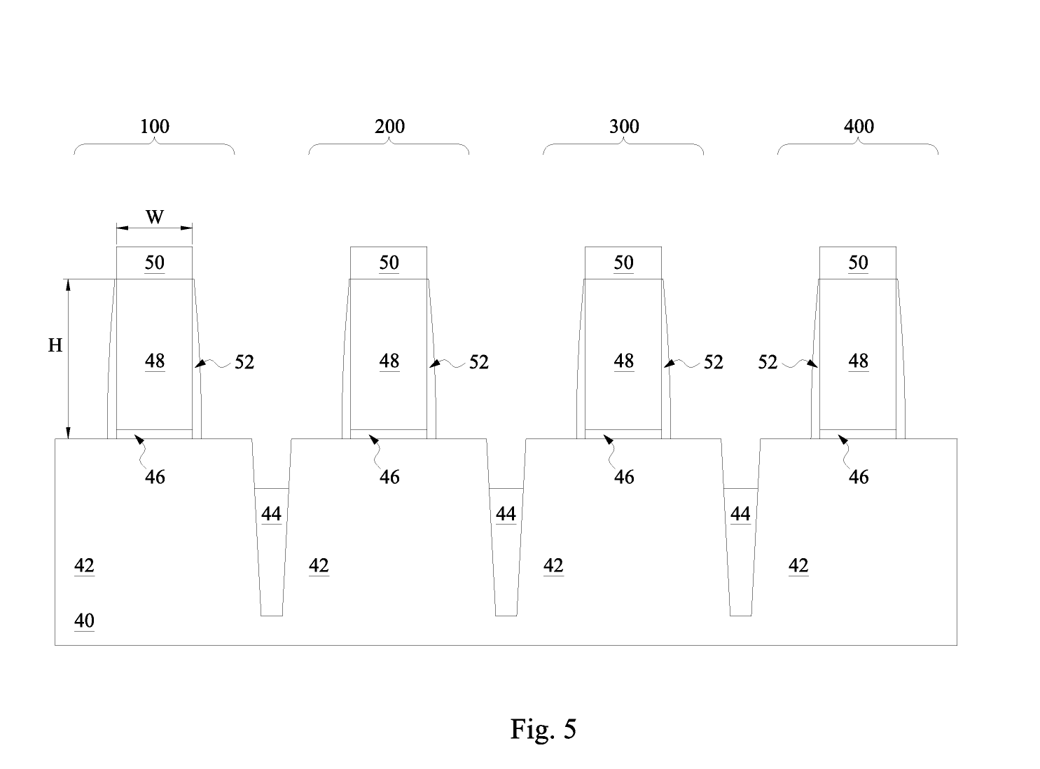

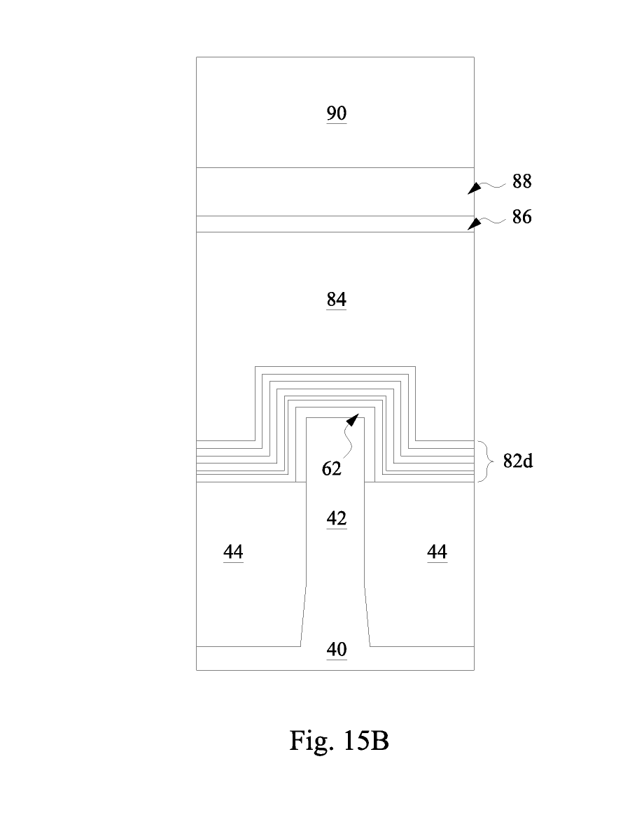

FIGS. 2 through 15B are cross-sectional views of intermediate stages in the manufacturing of finFETs in accordance with an exemplary embodiment. FIGS. 2, 3, and 4A illustrate reference cross-section A-A illustrated in FIG. 1, except for multiple fins. FIGS. 4B, 5 through 14, and 15A illustrate reference cross-section B-B illustrated in FIG. 1, except for multiple finFETs. FIG. 15B illustrates reference cross-section A-A of a finFET illustrated in FIG. 15A.

FIG. 2 illustrates a substrate 40. The substrate 40 may be a semiconductor substrate, such as a bulk semiconductor substrate, a semiconductor-on-insulator (SOI) substrate, a multi-layered or gradient substrate, or the like. The substrate 40 may include a semiconductor material, such as an elemental semiconductor including Si and Ge; a compound or alloy semiconductor including SiC, SiGe, GaAs, GaP, GaAsP, AlInAs, AlGaAs, GaInAs, InAs, GaInP, InP, InSb, and/or GaInAsP; or a combination thereof. The substrate 40 may be doped or un-doped. In a specific example, the substrate 40 is a bulk silicon substrate.

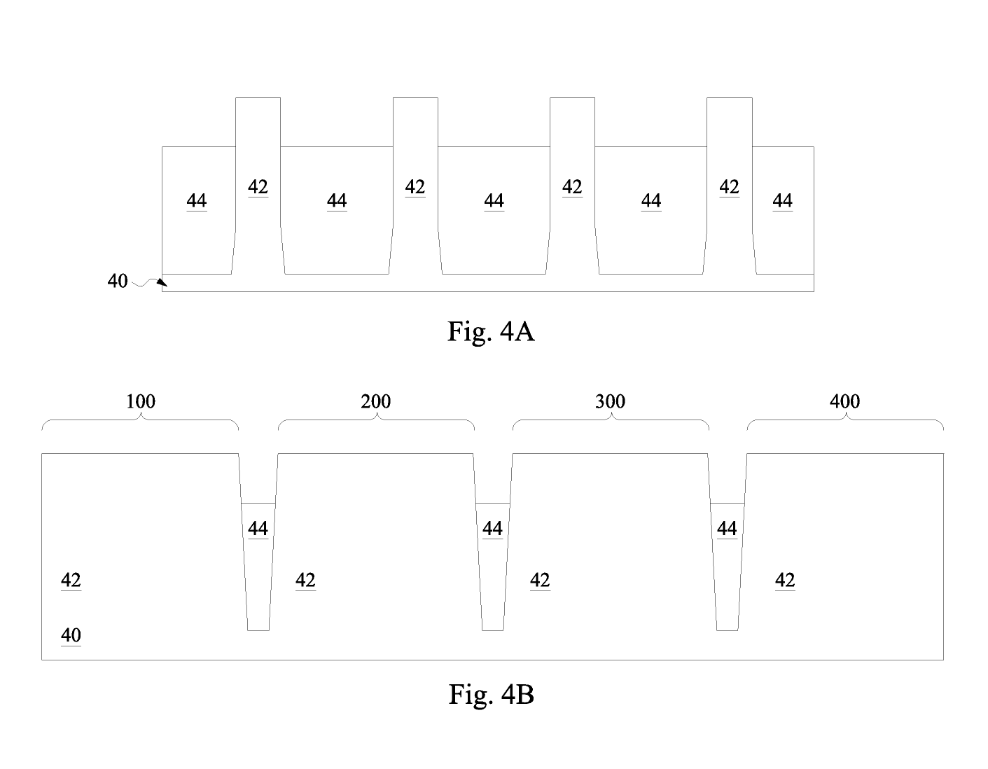

FIG. 3 illustrates the formation of fins 42 and isolation regions 44 between neighboring fins 42. In FIG. 3, fins 42 are formed in the substrate 40. In some embodiments, the fins 42 may be formed in the substrate 40 by etching trenches in the substrate 40. The etching may be any acceptable etch process, such as a reactive ion etch (RIE), neutral beam etch (NBE), the like, or a combination thereof. The etch may be anisotropic.

Further in FIG. 3, an insulation material is formed between neighboring fins 42 to form the isolation regions 44. The insulation material may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by a FCVD process. An anneal process may be performed once the insulation material is formed. Further in FIG. 3, a planarization process, such as a chemical mechanical polish (CMP), may remove any excess insulation material and form top surfaces of the isolation regions 44 and top surfaces of the fins 42 that are co-planar.

Although not specifically illustrated, appropriate wells may be formed in the fins 42 and/or substrate 40. For example, a p-well may be formed in a first region 100 and a second region 200 (illustrated in FIG. 4B and subsequent figures) of the substrate 40 where n-type devices, such as n-type finFETs, are to be formed, and an n-well may be formed in a third region 300 and a fourth region 400 of the substrate 40 (illustrated in FIG. 4B and subsequent figures) where p-type devices, such as p-type finFETs, are to be formed.

For example, to form a p-well in the first region 100 and the second region 200, a photoresist can formed over the fins 42 and the isolation regions 44 in the third region 300 and the fourth region 400 of the substrate 40. The photoresist can be patterned to expose the first region 100 and the second region 200 of the substrate 40. The photoresist can be formed by using a spin-on technique and can be patterned using acceptable photolithography techniques. Once the photoresist is patterned, a p-type impurity implant can be performed in the first region 100 and the second region 200, and the photoresist may act as a mask to substantially prevent p-type impurities from being implanted into the third region 300 and the fourth region 400. The p-type impurities may be boron, BF₂, or the like implanted in the first region 100 and the second region 200 to a concentration of equal to or less than 10¹⁸ cm⁻³, such as between about 10¹⁷ cm⁻³ and about 10¹⁸ cm⁻³. After the implant, the photoresist can be removed, such as by an acceptable ashing process.

Further, to form an n-well in the third region 300 and the fourth region 400, a photoresist can be formed over the fins 42 and the isolation regions 44 in the first region 100 and the second region 200 of the substrate. The photoresist can be patterned to expose the third region 300 and the fourth region 400 of the substrate 40. The photoresist can be formed by using a spin-on technique and can be patterned using acceptable photolithography techniques. Once the photoresist is patterned, an n-type impurity implant may be performed in the third region 300 and the fourth region 400, and the photoresist may act as a mask to substantially prevent n-type impurities from being implanted into the first region 100 and the second region 200. The n-type impurities may be phosphorus, arsenic, or the like implanted in the third region 300 and the fourth region 400 to a concentration of equal to or less than 10¹⁸ cm⁻³, such as between about 10¹⁷ cm⁻³ and about 10¹⁸ cm⁻³. After the implant, the photoresist can be removed, such as by an acceptable ashing process. After the implants, an anneal may be performed to activate the p-type and n-type impurities that were implanted. The implantations may form a p-well in the first region 100 and the second region 200 and an n-well in the third region 300 and the fourth region 400.

In FIGS. 4A and 4B, the isolation regions 44 are recessed, such as to form Shallow Trench Isolation (STI) regions. The isolation regions 44 are recessed such that fins 42 protrude from between neighboring isolation regions 44. The isolation regions 44 may be recessed using an acceptable etching process, such as one that is selective to the material of the isolation regions 44. For example, a chemical oxide removal using a CERTAS® etch or an Applied Materials SICONI tool or dilute hydrofluoric (dHF) acid may be used.

A person having ordinary skill in the art will readily understand that the process described with respect to FIGS. 2, 3, 4A, and 4B is just one example of how fins may be formed. In other embodiments, a dielectric layer can be formed over a top surface of the substrate 40; trenches can be etched through the dielectric layer; epitaxial fins can be epitaxially grown in the trenches; and the dielectric layer can be recessed such that the homoepitaxial and/or heteroepitaxial structures protrude from the dielectric layer to form epitaxial fins. It may be advantageous to epitaxially grow a material or epitaxial fin structure for n-type finFETs different from the material or epitaxial fin structure for p-type finFETs.

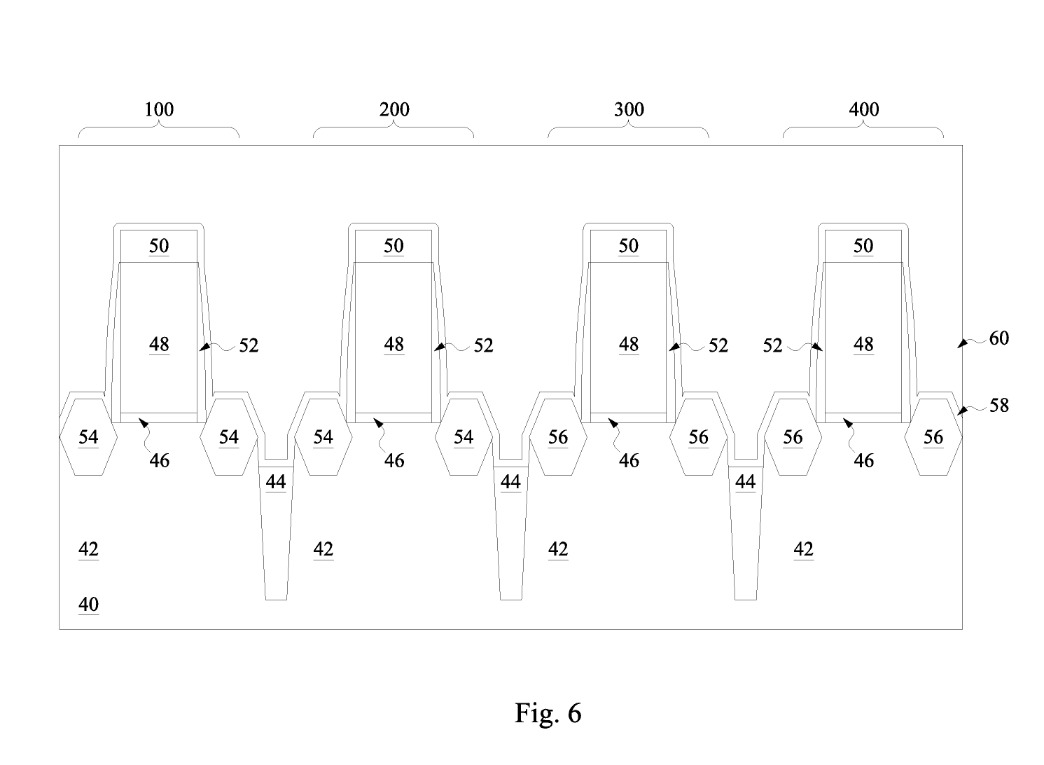

In FIG. 5, a dummy dielectric layer is formed on the fins 42. The dummy dielectric layer may be, for example, silicon oxide, silicon nitride, a combination thereof, or the like, and may be deposited or thermally grown according to acceptable techniques, such as CVD, thermal oxidation, or the like. A dummy gate layer is formed over the dummy dielectric layer, and a mask layer is formed over the dummy gate layer. The dummy gate layer may be deposited, such as by using CVD or the like, over the dummy dielectric layer and then planarized, such as by a CMP. The mask layer may be deposited, such as by using CVD or the like, over the dummy gate layer. The dummy gate layer may comprise, for example, polysilicon, although other materials that have a high etching selectivity may also be used. The mask layer may comprise, for example, silicon nitride, silicon oxynitride, silicon carbon nitride, or the like.

Further in FIG. 5, the mask layer may be patterned using acceptable photolithography and etching techniques to form masks 50. The pattern of the masks 50 then may be transferred to the dummy gate layer and dummy dielectric layer by an acceptable etching technique to form dummy gates 48 and dummy gate dielectrics 46 from the dummy gate layer and the dummy dielectric layer, respectively. The etching may comprise an acceptable anisotropic etching, such as RIE, NBE, or the like. A width W of the dummy gates 48 and dummy gate dielectrics 46 can be in range from about 10 nm to about 300 nm, such as about 16 nm. Each stack of a dummy gate 48 and a dummy gate dielectric 46 has a combined height H. The height H can be in range from about 40 nm to about 100 nm, such as about 70 nm. An aspect ratio of the height to width W can be in a range from about 0.1 to about 10, such as about 6. The dummy gates 48 cover respective channel regions of the fins 42. The dummy gates 48 may also have a lengthwise direction substantially perpendicular to the lengthwise direction of respective fins 42.

Although not specifically illustrated, implants for lightly doped source/drain (LDD) regions may be performed. Similar to the implants discussed above, a mask, such as a photoresist, may be formed over the third region 300 and the fourth region 400, e.g., for p-type devices, while exposing the first region 100 and the second region 200, e.g., for n-type devices, and n-type impurities may be implanted into the exposed fins 42 in the first region 100 and the second region 200. The mask may then be removed. Subsequently, a mask, such as a photoresist, may be formed over the first region 100 and the second region 200 while exposing the third region 300 and the fourth region 400, and p-type impurities may be implanted into the exposed fins 42 in the third region 300 and the fourth region 400. The mask may then be removed. The n-type impurities may be the any of the n-type impurities previously discussed, and the p-type impurities may be the any of the p-type impurities previously discussed. The lightly doped source/drain regions may have a concentration of impurities from about 10¹⁵ cm⁻³ to about 10¹⁶ cm⁻³. An anneal may be used to activate the implanted impurities.

Further in FIG. 5, gate spacers 52 are formed along sidewalls of the dummy gates 48 and dummy gate dielectrics 46. The gate spacers 52 may be formed by conformally depositing, such as by CVD or the like, a material and subsequently anisotropically etching the material. The material of the gate spacers 52 may be silicon nitride, silicon carbon nitride, a combination thereof, or the like.

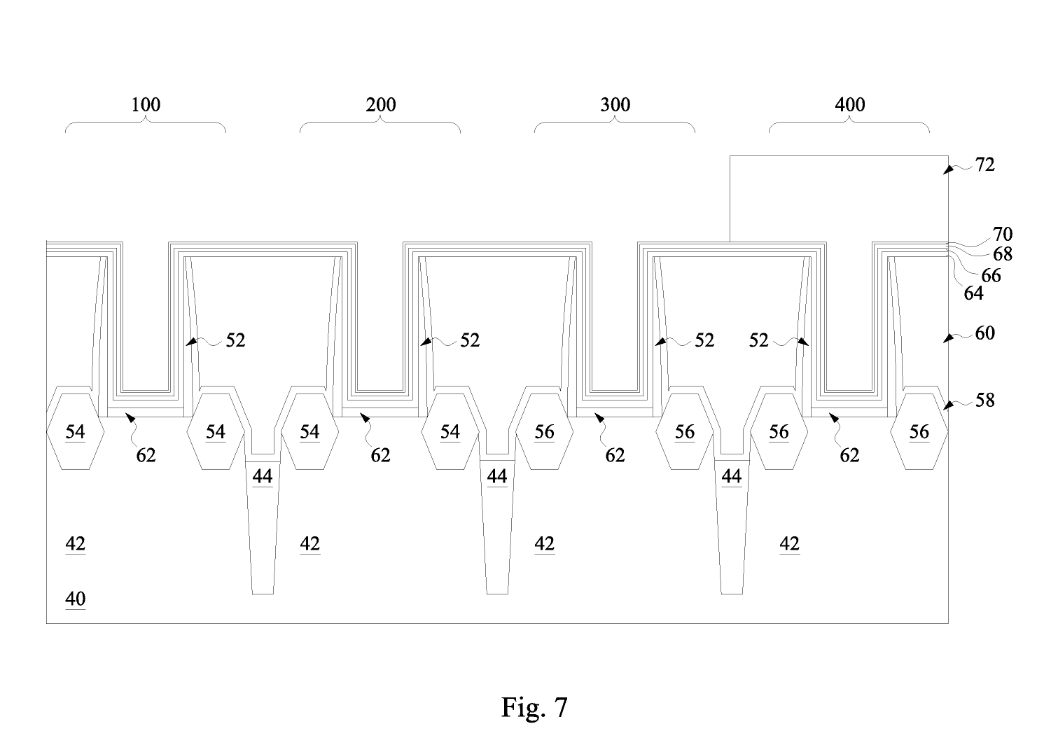

In FIG. 6, epitaxial source/drain regions 54 and 56 are formed in the source/drain region of the fins 42. In the first region 100 and the second region 200, epitaxial source/drain regions 54 are formed in the source/drain regions of the fins 42 such that each dummy gate 48 is disposed between ones of a respective pair of the epitaxial source/drain regions 54 in each fin 42. In the third region 300 and the fourth region 400, epitaxial source/drain regions 56 are formed in the source/drain regions of the fins 42 such that each dummy gate 48 is disposed between ones of a respective pair of the epitaxial source/drain regions 54 in each fin 42.

The epitaxial source/drain regions 54 in the first region 100 and the second region 200, e.g., for n-type devices, may be formed by masking, such as with a hard mask, the third region 300 and the fourth region 400, e.g., for p-type devices. Then, source/drain regions of the fins 42 in the first region 100 and the second region 200 are etched to form recesses. The etch may be any appropriate etch selective to the fins 42 and may be anisotropic. The epitaxial source/drain regions 54 in the first region 100 and the second region 200 are then epitaxially grown in the recesses. The epitaxial growth may be by using Metal-Organic CVD (MOCVD), Molecular Beam Epitaxy (MBE), Liquid Phase Epitaxy (LPE), Vapor Phase Epitaxy (VPE), the like, or a combination thereof. The epitaxial source/drain regions 54 may comprise any acceptable material, such as appropriate for n-type finFETs. For example, the epitaxial source/drain regions 54 may comprise silicon, SiC, SiCP, SiP, or the like. The epitaxial source/drain regions 54 may have surfaces raised from respective outer surfaces of the fins 42 and may have facets. The mask may then be removed, such as by using an etch selective to the material of the mask.

The epitaxial source/drain regions 56 in the third region 300 and the fourth region 400 may be formed by masking, such as with a hard mask, the first region 100 and the second region 200. Then, source/drain regions of the fins 42 in the third region 300 and the fourth region 400 are etched to form recesses. The etch may be any appropriate etch selective to the fins 42 and may be anisotropic. The epitaxial source/drain regions 56 in the third region 300 and the fourth region 400 are then epitaxially grown in the recesses. The epitaxial growth may be by using MOCVD, MBE, LPE, VPE, the like, or a combination thereof. The epitaxial source/drain regions 56 may comprise any acceptable material, such as appropriate for p-type finFETs. For example, the epitaxial source/drain regions 56 may comprise SiGe, SiGeB, Ge, GeSn, or the like. The epitaxial source/drain regions 56 may have surfaces raised from respective outer surfaces of the fins 42 and may have facets. The mask may then be removed, such as by using an etch selective to the material of the mask.

The epitaxial source/drain regions 54 and 56 and/or source/drain regions of the fins 42 may be implanted with dopants, similar to the process previously discussed for forming lightly doped source/drain regions, followed by an anneal. The source/drain regions may have an impurity concentration of between about 10¹⁹ cm⁻³ and about 10²¹ cm⁻³. The n-type impurities for source/drain regions in the first region 100 and the second region 200, e.g., for n-type devices, may be any of the n-type impurities previously discussed, and the p-type impurities for source/drain regions in the third region 300 and the fourth region 400, e.g., for p-type devices, may be any of the p-type impurities previously discussed. In other embodiments, the epitaxial source/drain regions 54 and 56 may be in situ doped during growth.

Further in FIG. 6, an etch stop layer (ESL) 58 is conformally formed on epitaxial source/drain regions 54 and 56, gate spacers 52, masks 50, and isolation regions 44. In some embodiments, the ESL 58 may comprise silicon nitride, silicon carbonitride, or the like, formed using Atomic Layer Deposition (ALD), chemical vapor deposition (CVD), the like, or a combination thereof. A bottom inter-layer dielectric (ILD0) 60 is deposited over the ESL 58. ILD0 60 may comprise Phospho-Silicate Glass (PSG), Boro-Silicate Glass (BSG), Boron-Doped Phospho-Silicate Glass (BPSG), undoped Silicate Glass (USG), or the like, and may be deposited by any suitable method, such as CVD, plasma-enhanced CVD (PECVD), FCVD, the like, or a combination thereof.

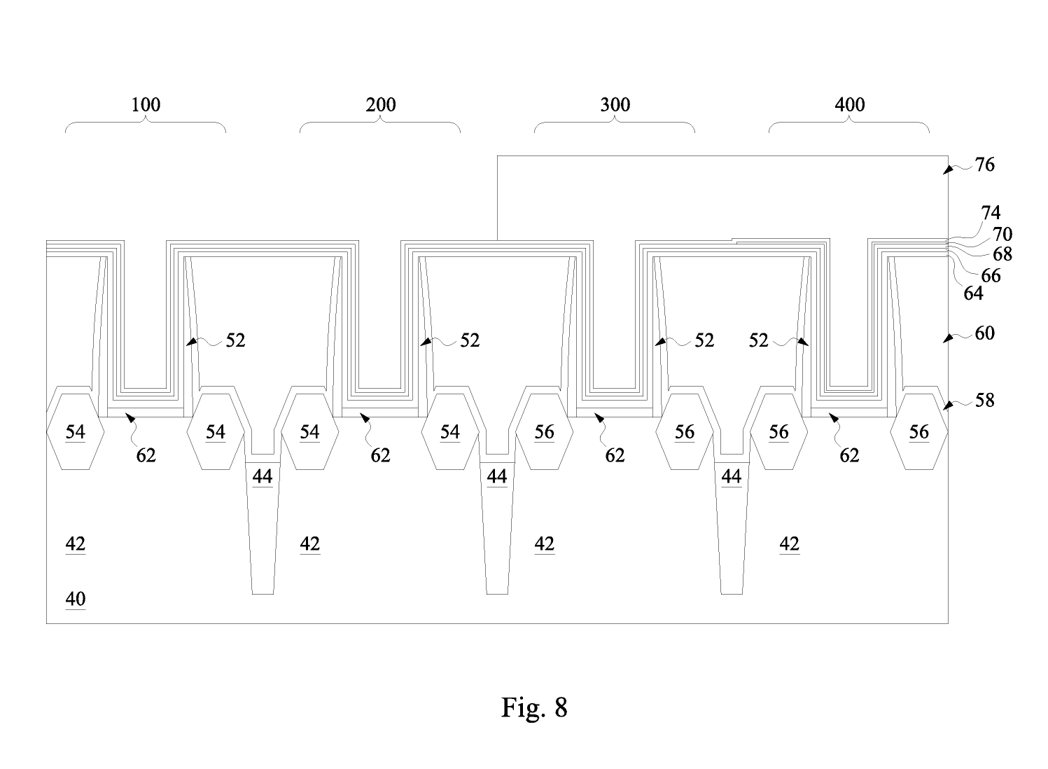

In FIG. 7, a planarization process, such as a CMP, is performed to level the top surface of ILD0 60 with the top surfaces of the dummy gates 48. The CMP may also remove the masks 50 and the ESL 58 from over the dummy gates 48. Accordingly, top surfaces of the dummy gates 48 are exposed through the ILD0 60. The dummy gates 48 and the dummy gate dielectrics 46 are removed in an etching step(s), so that openings through the ILD0 60 and defined by the gate spacers 52 are formed to the fins 42. Each of the openings may have an aspect ratio corresponding to the width W and height H discussed above with respect to FIG. 5 since the openings are defined by the removal of the dummy gates 48 and dummy gate dielectrics 46. Each opening exposes a channel region of a respective fin 42. Each channel region is disposed between neighboring pairs of epitaxial source/drain regions 54 and 56. The etching step(s) may be selective to the materials of the dummy gates 48 and the dummy gate dielectrics 46, which etching may be a dry or wet etching. During the etching, the dummy gate dielectrics 46 may be used as an etch stop layer when the dummy gates 48 are etched. The dummy gate dielectric 46 may then be etched after the removal of the dummy gates 48. Although not specifically illustrated, depending on the similarity of materials used for the ILD0 60 and the dummy gate dielectrics 46, the ILD0 60 may be recessed when the dummy gate dielectrics 46 are removed, and this recessing may cause portions of the ESL 58 and/or gate spacers 52 to protrude above the top surface of the ILD0 60.

An interfacial dielectric 62 is formed in each opening and on the fins 42. The interfacial dielectric 62 may be, for example, an oxide or the like formed by thermal oxidation or the like. A thickness of the interfacial dielectric 62 may be in a range from about 10 Å to about 100 Å, such as about 40 Å. A gate dielectric layer 64 is then formed conformally on the top surface of the ILD0 60 and in the openings along sidewalls of the gate spacers 52 and on the interfacial dielectric 62. In some embodiments, the gate dielectric layer 64 comprises a high-k dielectric material, and in these embodiments, the gate dielectric layer 64 may have a k value greater than about 7.0, and may include a metal oxide or a silicate of Hf, Al, Zr, La, Mg, Ba, Ti, Pb, and combinations thereof. The formation methods of gate dielectric layer 64 may include ALD, CVD, Molecular-Beam Deposition (MBD), the like, or a combination thereof. A thickness of the gate dielectric layer 64 may be in a range from about 10 Å to about 100 Å, such as about 30 Å.

A capping layer is then formed conformally on the gate dielectric layer 64. In the illustrated embodiment, the capping layer comprises a first sub-layer 66 and a second sub-layer 68. In some embodiments, the capping layer may be a single layer or may comprise additional sub-layers. The capping layer may function as a barrier layer to prevent a subsequently deposited metal-containing material from diffusing into the gate dielectric layer 64. Further, the second sub-layer 68, as illustrated, can function as an etch stop during the formation of work function tuning layers in various regions 100, 200, 300 and 400 if the first sub-layer 66 is formed from a same material as the work function tuning layers, as will become clearer subsequently. The first sub-layer 66 can comprise titanium nitride (TiN) or the like deposited conformally on the gate dielectric layer 64 by ALD, CVD, or the like. The second sub-layer 68 can comprise tantalum nitride (TaN) or the like deposited conformally on the first sub-layer 66 by ALD, CVD, or the like. A thickness of the capping layer may be in a range from about 5 Å to about 50 Å, such as about 10 Å. In the illustrated embodiment, a thickness of the first sub-layer 66 may be in a range from about 5 Å to about 50 Å, such as about 20 Å, and a thickness of the second sub-layer 68 may be in a range from about 5 Å to about 50 Å, such as about 20 Å.

A first work function tuning layer 70 is then formed conformally on the capping layer, e.g., on the second sub-layer 68. The first work function tuning layer 70 may be any acceptable material to tune a work function of a device to a desired amount given the application of the device to be formed, and may be deposited using any acceptable deposition process. In some embodiments, the first work function tuning layer 70 comprises titanium aluminum (TiAl) or the like deposited by ALD, CVD, or the like. A thickness of the first work function tuning layer 70 may be in a range from about 10 Å to about 100 Å, such as about 30 Å.

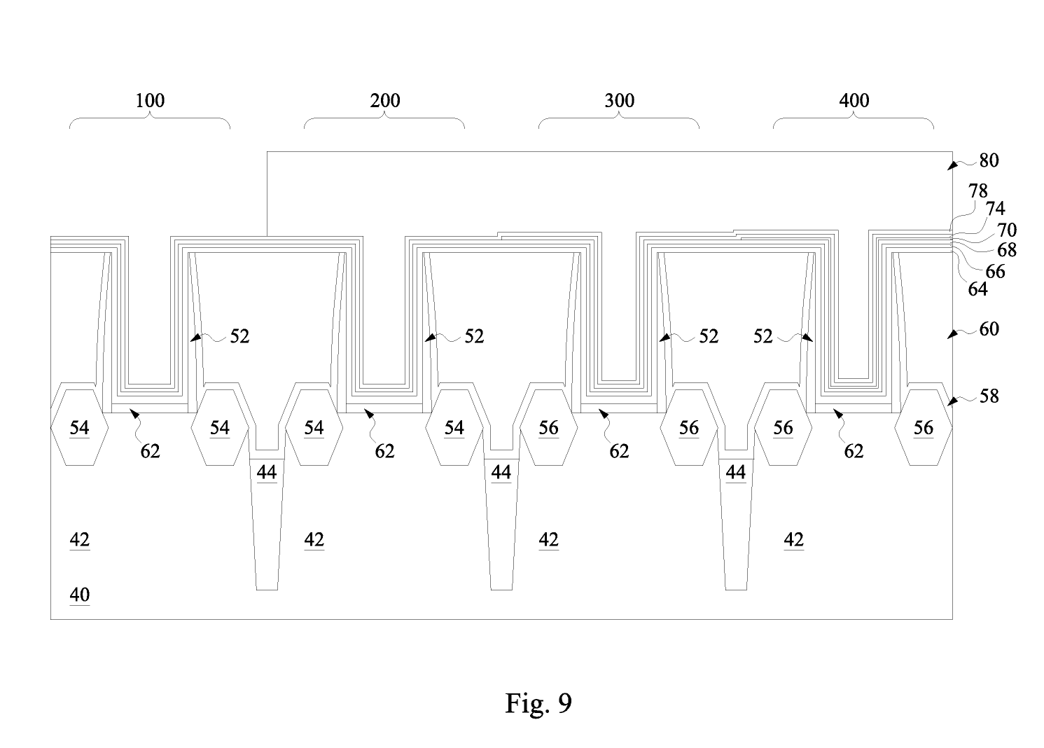

A mask 72 is then patterned over the first work function tuning layer 70 in the fourth region 400, while the first work function tuning layer 70 in the first, second, and third regions 100, 200, and 300 is exposed. In some embodiments, the mask 72 is a photoresist, which can be formed over the fourth region 400. The photoresist can be patterned to expose the first, second, and third regions 100, 200, and 300. The photoresist can be formed by using a spin-on technique and can be patterned using acceptable photolithography techniques. Once the mask 72 is patterned, an etch selective to the first work function tuning layer 70 is performed to remove the first work function tuning layer 70 from the first, second, and third regions 100, 200, and 300, as illustrated in FIG. 8. The second sub-layer 68 in the first, second, and third regions 100, 200, and 300 may act as an etch stop during this etching. The mask 72 is then removed, such as by using an appropriate ashing processing if the mask 72 is a photoresist.

Further in FIG. 8, a second work function tuning layer 74 is then formed conformally on the capping layer, e.g., on the second sub-layer 68, in the first, second, and third regions 100, 200, and 300 and conformally on the first work function tuning layer 70 in the fourth region 400. The second work function tuning layer 74 may be any acceptable material to tune a work function of a device to a desired amount given the application of the device to be formed, and may be deposited using any acceptable deposition process. In some embodiments, the second work function tuning layer 74 comprises titanium nitride (TiN) or the like deposited by ALD, CVD, or the like. A thickness of the second work function tuning layer 74 may be in a range from about 10 Å to about 50 Å, such as about 20 Å.

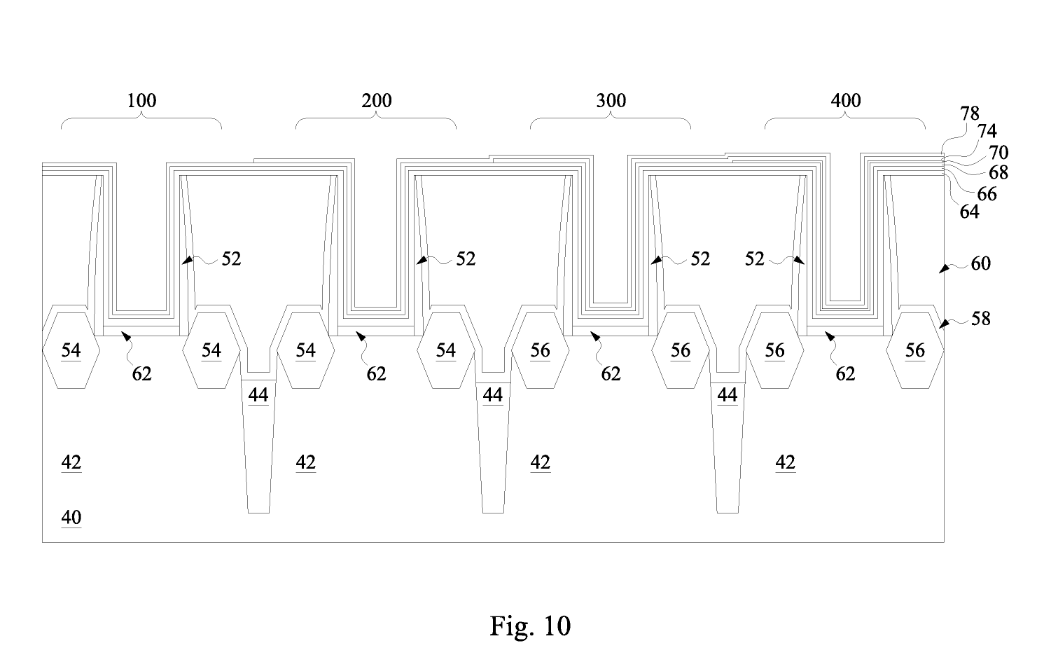

A mask 76 is then patterned over the second work function tuning layer 74 in the third and fourth regions 300 and 400, while the second work function tuning layer 74 in the first and second regions 100 and 200 is exposed. In some embodiments, the mask 76 is a photoresist, which can be formed over the third and fourth regions 300 and 400. The photoresist can be patterned to expose the first and second regions 100 and 200. The photoresist can be formed by using a spin-on technique and can be patterned using acceptable photolithography techniques. Once the mask 76 is patterned, an etch selective to the second work function tuning layer 74 is performed to remove the second work function tuning layer 74 from the first and second regions 100 and 200, as illustrated in FIG. 9. The second sub-layer 68 in the first and second regions 100 and 200 may act as an etch stop during this etching. The mask 76 is then removed, such as by using an appropriate ashing processing if the mask 76 is a photoresist.

Further in FIG. 9, a third work function tuning layer 78 is then formed conformally on the capping layer, e.g., on the second sub-layer 68, in the first and second regions 100 and 200 and conformally on the second work function tuning layer 74 in the third and fourth regions 300 and 400. The third work function tuning layer 78 may be any acceptable material to tune a work function of a device to a desired amount given the application of the device to be formed, and may be deposited using any acceptable deposition process. In some embodiments, the third work function tuning layer 78 comprises titanium nitride (TiN) or the like deposited by ALD, CVD, or the like. A thickness of the third work function tuning layer 78 may be in a range from about 10 Å to about 50 Å, such as about 20 Å.

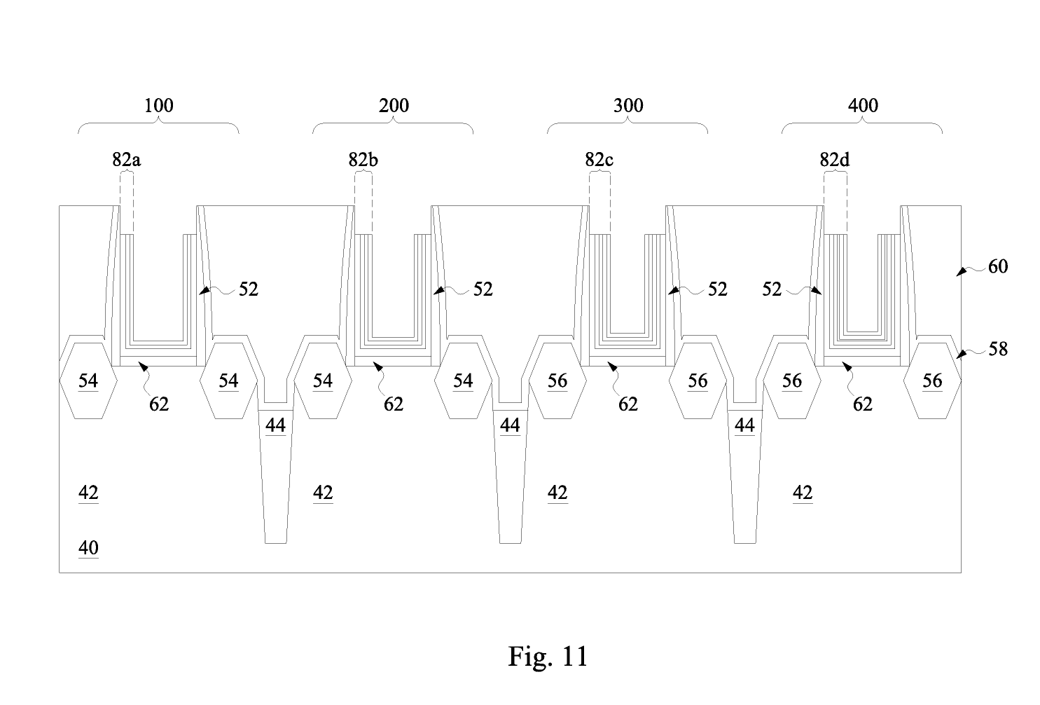

A mask 80 is then patterned over the third work function tuning layer 78 in the second, third, and fourth regions 200, 300, and 400, while the third work function tuning layer 78 in the first region 100 is exposed. In some embodiments, the mask 80 is a photoresist, which can be formed over the second, third, and fourth regions 200, 300, and 400. The photoresist can be patterned to expose the first region 100. The photoresist can be formed by using a spin-on technique and can be patterned using acceptable photolithography techniques. Once the mask 80 is patterned, an etch selective to the third work function tuning layer 78 is performed to remove the third work function tuning layer 78 from the first region 100, as illustrated in FIG. 10. The second sub-layer 68 in the first region 100 may act as an etch stop during this etching. The mask 80 is then removed, such as by using an appropriate ashing processing if the mask 80 is a photoresist.

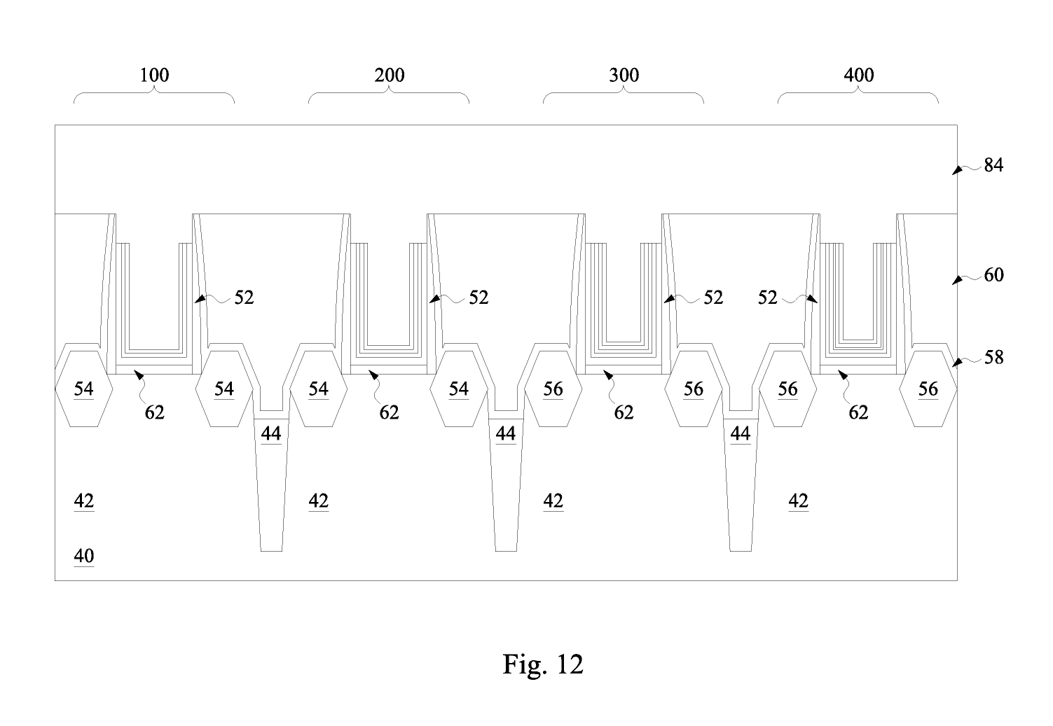

In FIG. 11, the gate dielectric layer 64, capping layer (including sub-layers 66 and 68), and work function tuning layers 70, 74, and 78 are etched such that layered structures 82a, 82b, 82c, and 82d are formed in the first, second, third, and fourth regions 100, 200, 300, and 400, respectively. The etch can be, for example, a dry etch that substantially etches upper portions of the layers without etching lower portions of the layers in the openings. For example, the etchant gas can be selective to the materials of the layers, and process parameters can be modified to achieve the structure in FIG. 11. Aspect ratios of the openings and/or necking of the layers at the corners of the openings may factor into the etch not substantially etching bottom portions of the layers in the openings. In other embodiments, a sacrificial material can be deposited in the openings to prevent the lower portions from being etched, and the sacrificial material may be selectively removed after the etch.

As illustrated, the layered structure 82a in the first region 100 includes the gate dielectric layer 64 and the capping layer (which includes the first sub-layer 66 and the second sub-layer 68). As illustrated, the layered structure 82b in the second region 200 includes the gate dielectric layer 64, the capping layer (which includes the first sub-layer 66 and the second sub-layer 68), and the third work function tuning layer 78. As illustrated, the layered structure 82c in the third region 300 includes the gate dielectric layer 64, the capping layer (which includes the first sub-layer 66 and the second sub-layer 68), the second work function tuning layer 74, and the third work function tuning layer 78. As illustrated, the layered structure 82d in the fourth region 400 includes the gate dielectric layer 64, the capping layer (which includes the first sub-layer 66 and the second sub-layer 68), the first work function tuning layer 70, the second work function tuning layer 74, and the third work function tuning layer 78.

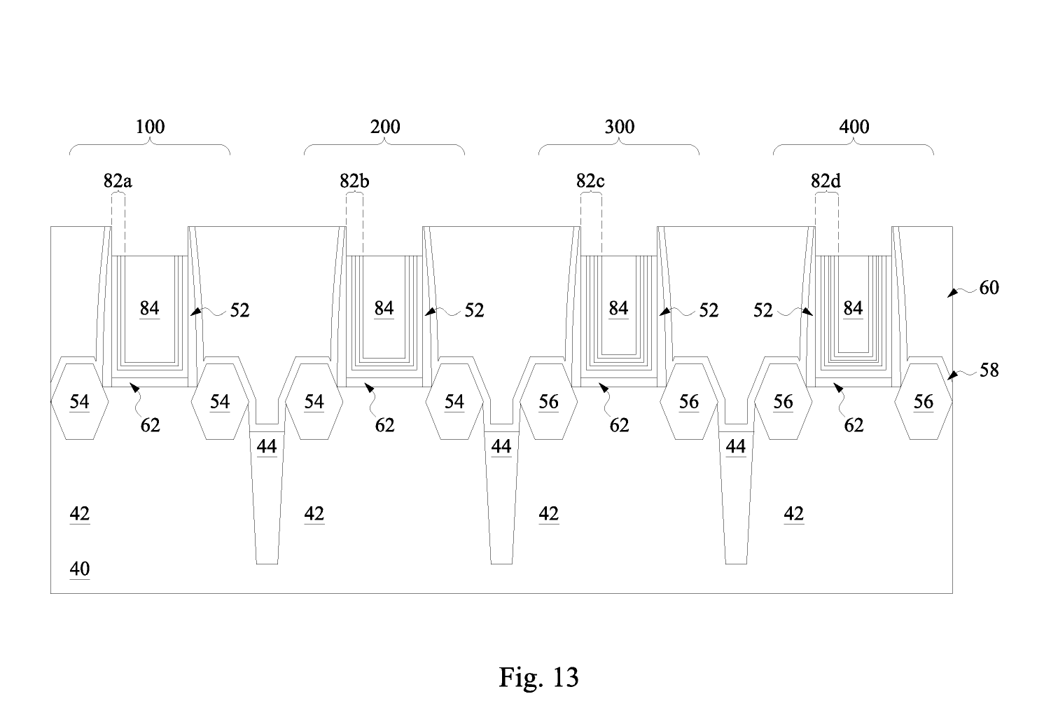

In FIG. 12, a conductive material 84 is deposited in the openings on the layered structures 82a, 82b, 82c, and 82d and on the ILD0 60. The conductive material 84 can include a metal, such as tungsten (W), aluminum (Al), cobalt (Co), ruthenium (Ru), combinations thereof or the like. The conductive material 84 can be deposited using CVD, physical vapor deposition (PVD), the like, or a combination thereof. The conductive material 84 at least fills the remaining portions, e.g., portions not filled by the layered structures 82a, 82b, 82c, and 82d, of the openings.

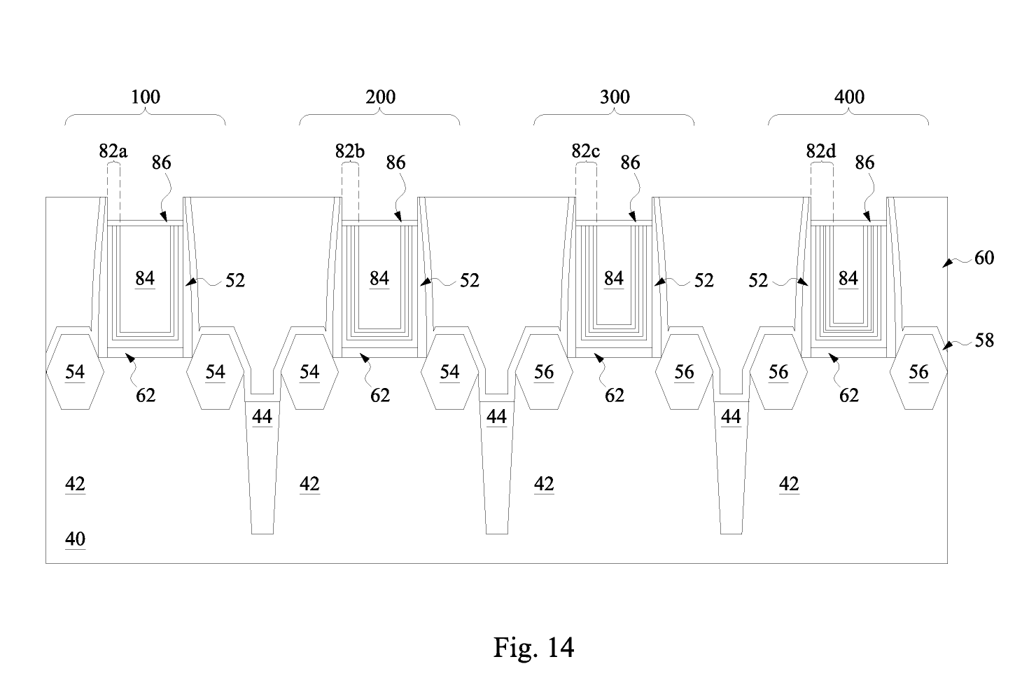

Next, a planarization process, such as a CMP, may be performed to remove the excess portions of conductive material 84, which excess portions are over the top surface of ILD0 60. Then, a controlled etch-back selective to the conductive material 84, and possibly selective to the layered structures 82a, 82b, 82c, and 82d, is performed to recess the conductive material 84, which results in the gate structures illustrated in FIG. 13, from the top surface of the ILD0 60.

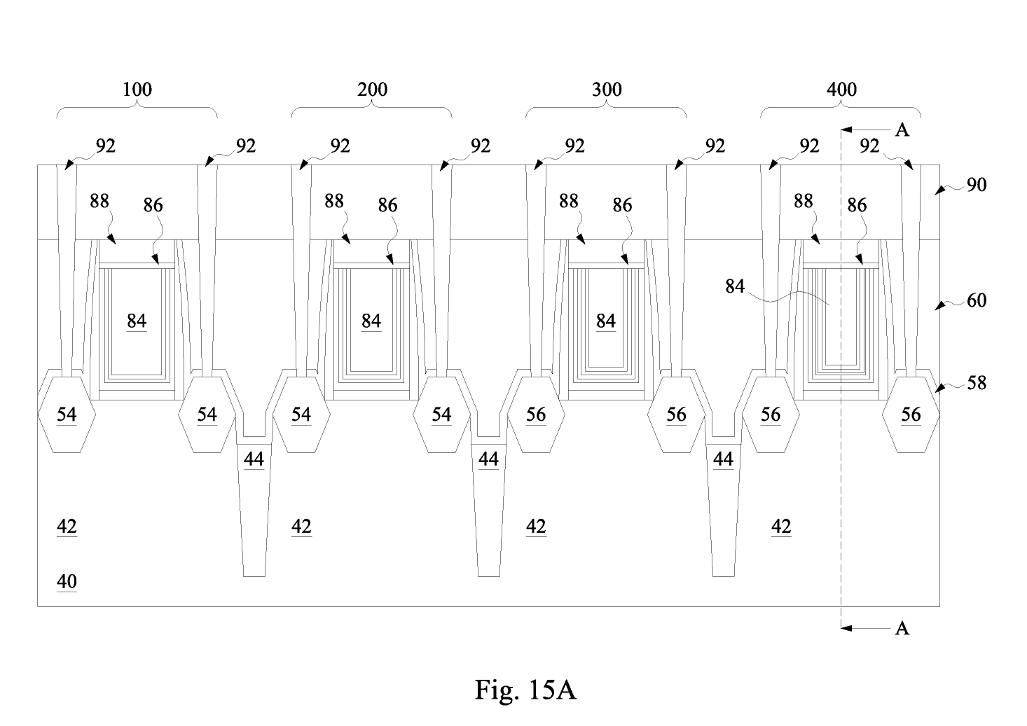

In FIG. 14, buffer layers 86 are formed on the conductive material 84 and the layered structures 82a, 82b, 82c, and 82d. In some embodiments, the buffer layers 86 are oxide layers. The oxide layer can be formed using a thermal oxidation, an oxygen-containing plasma treatment, or the like. An example of an oxygen-containing plasma treatment would be exposure to an oxygen (O₂) plasma or the like. The oxide layer could also be a native oxide formed by exposing the conductive material 84 and the layered structures 82a, 82b, 82c, and 82d to a natural, outside environment, such as by breaking a vacuum after the etch-back discussed with respect to FIG. 13. A thickness of the buffer layer 86 may be in a range from about 5 Å to about 50 Å, such as about 15 Å. The oxide layer may have a composition that corresponds to its underlying material. For example, if the conductive material is tungsten, the oxide layer can be tungsten oxide. The oxide layer may have a varying composition proximate portions that overlie any work function tuning layers 70, 74, and 78, the capping layer (including sub-layers 66 and 68), and the gate dielectric layer 64. In some embodiments, the thicknesses of these layers can be small compared to the width of the conductive material 84 at the oxide layer, and hence, the variance of composition can be small. The oxide layer can be substantially free from pores and/or voids and may be very dense. As an example, the oxide layer can have a density equal to or greater than about 1.5 g/cm³, such as greater than 2.0 g/cm³, such as in a range from about 1.5 g/cm³ to about 2.5 g/cm³.

In FIG. 15A, dielectric caps 88 are formed on the buffer layers 86. To form the dielectric caps 88, a cap dielectric layer can be deposited in the remaining portions of the openings above the buffer layers 86 and on the top surface of the ILD0 60. The cap dielectric layer may comprise silicon nitride, silicon carbonitride, or the like, formed using CVD, PECVD, or the like. The cap dielectric layer can then be planarized, such as by CMP, to form top surfaces co-planar with the top surface of the ILD0 60 thereby forming the dielectric caps.

An upper ILD (ILD1) 90 is deposited over the ILD0 60 and the dielectric caps 88, and contacts 92 are formed through the ILD1 90, ILD0 60, and ESL 58 to the epitaxial source/drain regions 54 and 56. ILD1 90 is formed of a dielectric material such as PSG, BSG, BPSG, USG, or the like, and may be deposited by any suitable method, such as CVD and PECVD. Openings for contacts 92 are formed through the ILD1 90, ILD0 60, and ESL 58. The openings may be formed using acceptable photolithography and etching techniques. A liner, such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, aluminum, nickel, or the like. A planarization process, such as a CMP, may be performed to remove excess material from a surface of the ILD1 90. The remaining liner and conductive material form contacts 92 in the openings. An anneal process may be performed to form a silicide at the interface between the epitaxial source/drain regions 54 and 56 and the contacts 92, respectively.

FIG. 15A illustrates a first device in the first region 100, which may be an ultra-low threshold voltage n-type finFET due to the layered structure 82a and conductive material 84 included in the gate structure. FIG. 15A also illustrates a second device in the second region 200, which may be a standard threshold voltage n-type finFET due to the layered structure 82b and conductive material 84 included in the gate structure. FIG. 15A further illustrates a third device in the third region 300, which may be a standard threshold voltage p-type finFET due to the layered structure 82c and conductive material 84 included in the gate structure. FIG. 15A likewise illustrates a fourth device in the fourth region 400, which may be an ultra-low threshold voltage p-type finFET due to the layered structure 82d and conductive material 84 included in the gate structure.

Although not explicitly shown, a person having ordinary skill in the art will readily understand that further processing steps may be performed on the structure in FIG. 15A. For example, various Inter-Metal Dielectrics (IMD) and their corresponding metallizations may be formed over ILD1 90.

FIG. 15B illustrates cross-section A-A of FIG. 15A to illustrate aspects of the gate structure formed in the fourth region 400. The interfacial dielectric 62 and the layered structure 82d are conformal along sidewalls of the fin 42. The gate structures in the first, second, and third regions 100, 200, and 300 have similar cross sections, except with the differences in layered structures 82a, 82b, and 82c previously discussed.

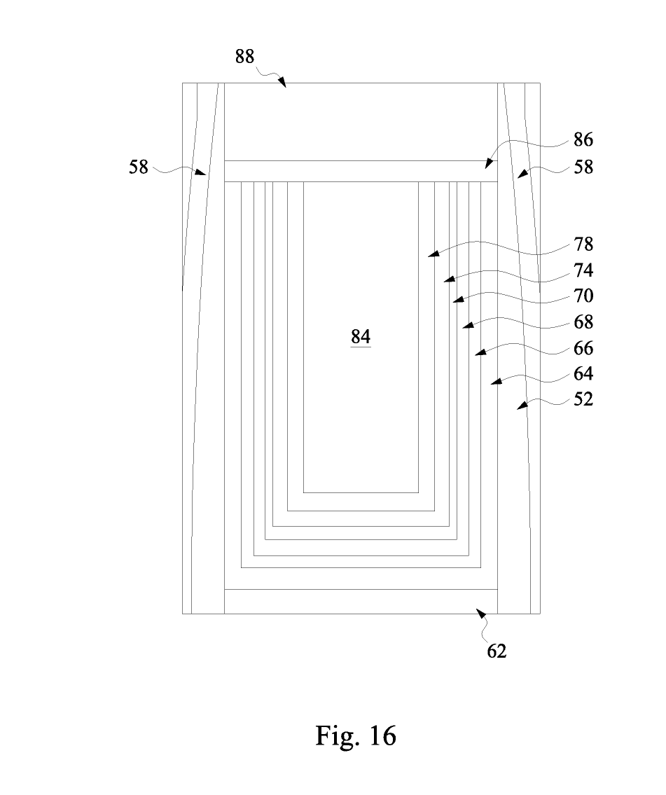

FIG. 16 is an enlarged view of the gate structure formed in the fourth region 400, which is shown to clarify the layers formed therein. The gate structures in the first, second, and third regions 100, 200, and 300 have similar cross sections, except with the differences in layered structures 82a, 82b, and 82c previously discussed.

Some embodiments may achieve advantages. By forming a buffer layer, such as an oxide layer, on the gate structure as described, adhesion between, for example, the conductive material, which may be a metal, and a subsequent dielectric layer, such as a dielectric cap, may be improved. This improved adhesion can reduce diffusion of the conductive material and delamination.

An embodiment is a method. A gate structure is formed. The gate structure includes a gate dielectric over a substrate, a work function tuning layer over the gate dielectric, and a metal-containing material over the work function tuning layer. A buffer layer is formed on the metal-containing material. A dielectric material is formed on the buffer layer.

Another embodiment is a method. A dummy gate structure is formed over a substrate. A first source/drain region and second source/drain region are formed in the substrate and on opposing sides of the dummy gate structure. An inter-layer dielectric is formed over the substrate and around the dummy gate structure. An opening is formed through the inter-layer dielectric by removing the dummy gate structure. A layered structure is formed conformally in the opening. The layered structure comprises a gate dielectric layer along sidewalls and a bottom surface of the opening and a capping layer along the gate dielectric layer. A metal electrode is formed on the layered structure and in the opening. An oxide layer is formed on the metal electrode and in the opening. A dielectric cap is formed on the oxide layer and in the opening.

A further embodiment is a structure. The structure comprises a first source/drain region and a second source/drain region in a substrate and a gate structure over the substrate and disposed between the first source/drain region and the second source/drain region. The gate structure comprises a high-k gate dielectric and a metal gate electrode. An oxide layer is on the metal gate electrode. A dielectric cap is on the oxide layer. An inter-layer dielectric is over the substrate and around the gate structure. A top surface of the inter-layer dielectric is co-planar with a top surface of the dielectric cap.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a gate structure comprising:
a gate dielectric over a substrate,
a work function tuning layer over the gate dielectric, and
a metal-containing material over the work function tuning layer;
forming a buffer layer on the metal-containing material; and
forming a dielectric material on the buffer layer.

2. The method of claim 1, wherein the buffer layer is an oxide of the metal-containing material.

3. The method of claim 1, wherein the forming the buffer layer comprises using an oxygen-containing plasma process.

4. The method of claim 1, wherein the forming the buffer layer comprises using a thermal oxidation process.

5. The method of claim 1, wherein the forming the buffer layer comprises breaking a vacuum to expose the metal-containing material to a natural environment.

6. The method of claim 1 further comprising:
forming a first source/drain region and a second source/drain region in the substrate and on opposing sides of the gate structure; and
forming an inter-layer dielectric over the substrate, the buffer layer being at a level lower than a top surface of the inter-layer dielectric, the dielectric material having a top surface co-planar with the top surface of the inter-layer dielectric.

7. The method of claim 1, wherein the forming the gate structure further comprises:
forming a dummy gate structure over the substrate,
forming a gate spacer along a sidewall of the dummy gate structure, and removing the dummy gate structure to form an opening exposing the substrate, the gate spacer defining a sidewall of the opening, and
wherein:
the gate dielectric is formed conformally in the opening, and
the forming the metal-containing material includes recessing the metal-containing material below a top portion of the gate spacer before forming the buffer layer.

8. A method comprising:
forming a dummy gate structure over a substrate;
forming a first source/drain region and second source/drain region in the substrate and on opposing sides of the dummy gate structure;
forming an inter-layer dielectric over the substrate and around the dummy gate structure;
forming an opening through the inter-layer dielectric by removing the dummy gate structure;
forming a layered structure conformally in the opening, the layered structure comprising a gate dielectric layer along sidewalls and a bottom surface of the opening and a capping layer along the gate dielectric layer;
forming a metal electrode on the layered structure and in the opening;
forming an oxide layer on the metal electrode and in the opening; and
forming a dielectric cap on the oxide layer and in the opening.

9. The method of claim 8, wherein the forming the oxide layer comprises using an oxygen-containing plasma process.

10. The method of claim 8, wherein the forming the oxide layer comprises using a thermal oxidation process.

11. The method of claim 8, wherein the forming the oxide layer comprises exposing the metal electrode to a natural environment.

12. The method of claim 8, wherein the oxide layer comprises an oxide of a metal of the metal electrode.

13. The method of claim 8, wherein a top surface of the dielectric cap is co-planar with a top surface of the inter-layer dielectric.

14. The method of claim 8, wherein a density of the oxide layer is equal to or greater than 1.5 g/cm³.

15. The method of claim 8, wherein the oxide layer is free from pores.

16. A structure comprising:
a first source/drain region and a second source/drain region in a substrate;
a gate structure over the substrate and disposed between the first source/drain region and the second source/drain region, the gate structure comprising a high-k gate dielectric and a metal gate electrode;
an oxide layer on the metal gate electrode;
a dielectric cap on the oxide layer; and
an inter-layer dielectric over the substrate and around the gate structure, a top surface of the inter-layer dielectric being co-planar with a top surface of the dielectric cap.

17. The structure of claim 16, wherein a density of the oxide layer is equal to or greater than 1.5 g/cm³.

18. The structure of claim 16, wherein the oxide layer is free from pores.

19. The structure of claim 16, wherein the oxide layer comprises an oxide of a metal of the metal gate electrode.

20. The structure of claim 16, wherein the gate structure further comprises a work function tuning material disposed between the high-k gate dielectric and the metal gate electrode.
